(19) United States
(12) Patent Application Publication
(10) Pub. No.: US 2006/0113489 A1
(43) Pub. Date: Jun. 1, 2006

(54) Optimization of beam utilization

(75) Inventors: Andrew M. Ray, Newburyport, MA (US); Michael A. Graf, Belmont, MA (US)

Correspondence Address: ESCHWEILER & ASSOCIATES, LLC;NATIONAL CITY BANK BUILDING, 629 EUCLID AVE., SUITE 1210, CLEVELAND, OH, 44114, US

(73) Assignee: Axcelis Technologies, Inc.

(21) Appl. No.: 11/000,023

(22) Filed: Nov. 30, 2004

(51) Int. Cl. H01J 37/08

(52) U.S. Cl. 250/492.21

(57) ABSTRACT

A method for optimizing an ion implantation, wherein a substrate is scanned in two dimensions through an ion beam. The method provides a process recipe comprising one or more of a current of an ion beam, a dosage of ions, and a number of substrate passes through the beam in a slow scan direction. The beam is profiled based on the process recipe, and a size of the beam is determined. One of a plurality of differing scan speeds in a fast scan direction is selected, based on a desired uniformity of the implantation and the process recipe. The process recipe is controlled, based on one or more of the desired uniformity, a throughput time for the substrate, a desired minimum ion beam current, and one or more substrate conditions. One of a plurality of speeds in a slow scan direction is selected, based on the dosage of the implantation.

### FIELD OF THE INVENTION

The present invention relates generally to semiconductor processing systems, and more specifically to a method for optimizing a utilization of an ion beam associated with an ion implantation of a semiconductor substrate.

### BACKGROUND OF THE INVENTION

In the semiconductor industry, various manufacturing processes are typically carried out on a substrate (e.g., a semiconductor wafer) in order to achieve various results on the substrate. Processes such as ion implantation, for example, can be performed in order to obtain a particular characteristic on or within the substrate, such as limiting a diffusivity of a dielectric layer on the substrate by implanting a specific type of ion. Conventionally, ion implantation processes are performed in either a batch process, wherein multiple substrates are processed simultaneously, or in a serial process, wherein a single substrate is individually processed. Traditional high-energy or high-current batch ion implanters, for example, are operable to achieve a short ion beam line, wherein a large number of wafers may be placed on a wheel or disk, and the wheel is simultaneously spun and radially translated through the ion beam, thus exposing all of the substrates surface area to the beam at various times throughout the process. Processing batches of substrates in such a manner, however, generally makes the ion implanter substantially large in size.

In a typical serial process, on the other hand, an ion beam is either scanned in a single axis across a stationary wafer, the wafer is translated in one direction past a fan-shaped, or scanned ion beam, or the wafer is translated in generally orthogonal axes with respect to a stationary ion beam or “spot beam”. The process of scanning or shaping a uniform ion beam, however, generally requires a complex and/or long beam line, which is generally undesirable at low energies.

Translating the wafer in generally orthogonal axes, however generally requires a uniform translation and/or rotation of either the ion beam or the wafer in order to provide a uniform ion implantation across the wafer. Furthermore, such a translation should occur in an expedient manner, in order to provide acceptable wafer throughput in the ion implantation process. However, such a uniform translation and/or rotation can be difficult to achieve, due, at least in part, to substantial inertial forces associated with moving the conventional devices and scan mechanisms during processing.

In a conventional ion implantation system wherein the wafer is moved relative to a fixed spot beam, the wafer is generally translated in what is termed a scanning or “fast scan” direction and a slower, generally orthogonal “slow scan” direction, wherein the speed of the wafer in the slow scan direction is controlled such that each scan of the wafer through the spot beam in the fast scan direction overlaps the previous scan to provide a generally uniform ion implantation. Typically, the speed of the substrate in the fast scan direction is fixed, wherein the slow scan velocity is adjusted in order to provide uniformity of the ion implantation across the wafer. However, such a fixed fast scan speed can provide sub-optimal ion beam utilization and/or substrate throughput.

Therefore, a need exists for a method for optimizing the scanning of a substrate relative to an ion beam, wherein the substrate is uniformly implanted with ions while optimizing the utilization of the ion source.

### SUMMARY OF THE INVENTION

The present invention overcomes the limitations of the prior art. Consequently, the following presents a simplified summary of the invention in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

The present invention is directed generally toward a method for optimizing a utilization of an ion beam during an ion implantation into a substrate. The ion implantation system, for example, is operable to scan or pass the substrate through the ion beam in a fast scan direction, as well as a generally orthogonal slow scan direction, wherein a speed of the substrate in the fast scan direction is significantly faster than a speed of the substrate in the slow scan direction.

According to one exemplary aspect of the present invention, a process recipe for the ion implantation is provided, wherein the process recipe comprises one or more of a current of the ion beam, a desired dosage of ions to be implanted in the substrate, and a number of passes of the substrate through the ion beam in the slow scan direction. In accordance with the process recipe, the ion beam is profiled, wherein a size of the ion beam is determined. One of a plurality of differing speeds of the substrate in the fast scan direction is further selected, wherein the selection is based, at least in part, on a desired maximum non-uniformity of the ion implantation and the process recipe. One or more parameters associated with process recipe are then controlled, wherein the control is based on one or more of the desired maximum non-uniformity, a throughput time for the substrate, a desired minimum ion beam current, and one or more substrate conditions, such as a maximum substrate temperature and a maximum desired momentum to be achieved by the substrate during scanning.

According to another exemplary aspect of the invention, one of a plurality of speeds of the substrate in the slow scan direction is selected, wherein the selection is based on the dosage of the ion implantation. In accordance with another exemplary aspect of the invention, another one of the plurality of speeds of the substrate in the fast scan direction is selected after controlling the process recipe, wherein the selection is based on a uniformity of an ion implantation associated with the controlled process recipe.

According to another exemplary aspect, the ion beam profile is determined based on one or more of empirical data associated with an ion implantation and a prediction of the beam profile based on the process recipe, wherein empirical data provides a more accurate optimization, while a predictive approach yields a faster optimization.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a plan view of an exemplary ion implantation system according to one aspect of the present invention.

FIG. 2 is a plan view of an exemplary scanning system and ion beam path according to another aspect of the present invention.

FIG. 3 is a block diagram of an exemplary method for optimizing an ion beam utilization efficiency of an ion implantation system according to another exemplary aspect of the invention.

FIG. 4 is a graph illustrating a non-uniformity of an ion implantation is association with a speed of a substrate in a fast-scan direction and a time taken for ion implantation on the substrate in accordance with another exemplary aspect of the present invention.

FIG. 5 is a block diagram of another exemplary method for optimizing an ion beam utilization efficiency of an ion implantation system according to yet another exemplary aspect of the invention.

### DETAILED DESCRIPTION OF THE INVENTION

The present invention is directed generally towards a method for optimizing an ion beam utilization efficiency when scanning a substrate relative to an ion beam in an ion implantation system. More particularly, the method provides an optimization based on one or more performance criteria associated with the ion implantation system. Accordingly, the present invention will now be described with reference to the drawings, wherein like reference numerals are used to refer to like elements throughout. It should be understood that the description of these aspects are merely illustrative and that they should not be taken in a limiting sense. In the following description, for purposes of explanation, numerous specific details are set forth in order to provide a thorough understanding of the present invention. It will be evident to one skilled in the art, however, that the present invention may be practiced without these specific details.

Productivity in ion implantation systems is generally defined by several factors. For example, productivity can be quantified by a capability of the system to generate a particular amount of ion beam current, a ratio between a number of ions that are generated by the system to a number of ions actually implanted in a substrate (e.g., a silicon wafer), and a ratio between an amount of time in which the substrate is being implanted with ions and an amount of time taken for positioning the substrate for ion implantation. The ratio of generated ions to ions actually implanted in the substrate, for example, is generally referred to as “ion beam utilization”, as will be discussed hereafter.

For low dose ion implants (e.g., ion implantations having a dosage of less than approximately 1×10¹⁴ cm²), a current of the ion beam typically ranges well below limitations in the capability of the ion implantation system, and the ion beam current can be increased in order to account for a potentially-low ion beam utilization. However, for high dose ion implants (e.g., ion implantations having a dosage of greater than approximately 1×10¹⁵ cm²), the ion beam current is typically at or near the maximum capability of the ion implantation system, and ion beam utilization has a much greater significance to the productivity of the system for optimal ion implantations. Such ion implantations are referred to as “beam current limited” implants, wherein the utilization of the ion beam is an important factor in determining the most advantageous usage of various types of ion implantation systems. For example, multiple-substrate ion implantation systems, or batch implanters, traditionally have a significantly higher ion beam utilization than single substrate systems, thus making the multiple-substrate systems the conventional tool of choice for high dose implants. However, single-substrate ion implantation systems, or serial systems, have various other advantages, such as contamination control, process lot size flexibility, and, in some configurations, incident beam angle control. Therefore, it would be highly desirable for the single-substrate system to be utilized if losses in productivity could be minimized.

Therefore, the present invention is directed to an optimization of ion beam utilization efficiency in a single-substrate ion implantation system, wherein various ion implantation operating parameters, such as linear scan speeds and accelerations of the substrate, are controlled based on characteristics of various individual processes performed by the ion implantation system. It should be noted, however, that the present invention can also be implemented in various other ion implantation systems, such as the above-mentioned batch implanters, and all such implementations are contemplated as falling within the scope of the present invention.

In a preferred embodiment of the present invention, several advantages over conventional methods using typical single-substrate or single-wafer ion implantation systems are provided. For example, conventional single-substrate ion implantation systems or serial implanters have generally fixed linear scan speeds and accelerations in one or more axes (e.g., in a slow-scan axis), and are not typically optimized for ion beam utilization efficiency. A control of various ion implantation operating parameters, as will be described hereafter, however, can lead to increases in various productivity efficiencies. For example, controlling linear scan speeds and accelerations of the substrate in two or more axes for a given process recipe can provide for an optimization of the utilization of the ion beam that is not generally possible in the conventional ion implantation systems.

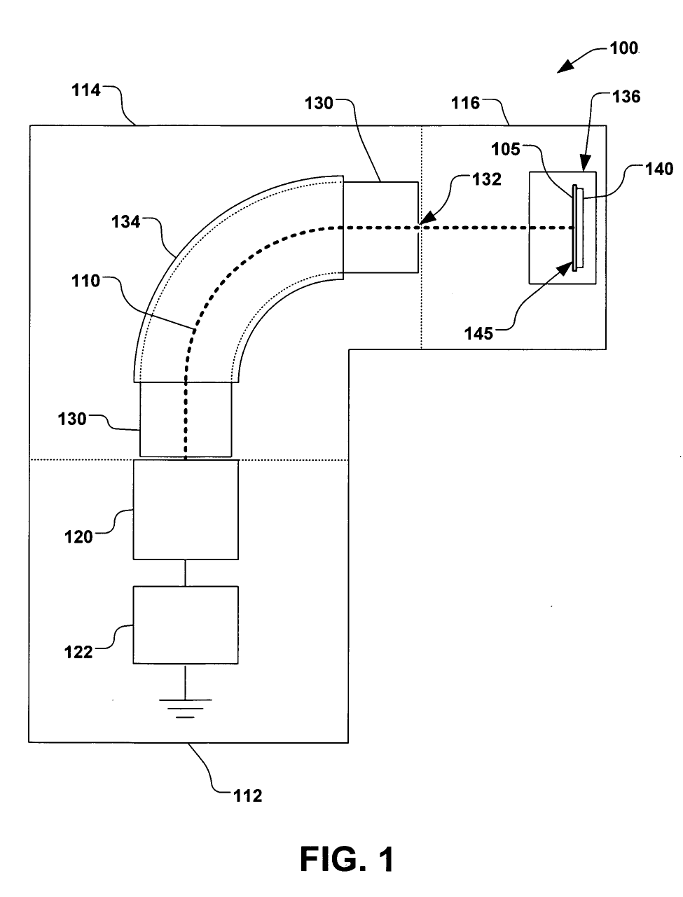

Referring now to the figures, in accordance with one exemplary aspect of the present invention, FIG. 1 illustrates an exemplary two-dimensional mechanically-scanned single-substrate ion implantation system 100, wherein the system is operable to mechanically scan a substrate 105 through an ion beam 110. As stated above, various aspects of the present invention may be implemented in association with any type of ion implantation apparatus, including, but not limited, to the exemplary system 100 of FIG. 1. The exemplary ion implantation system 100 comprises a terminal 112, a beamline assembly 114, and an end station 116 that forms a process chamber in which the ion beam 110 is directed to a workpiece location. An ion source 120 in the terminal 112 is powered by a power supply 122 to provide an extracted ion beam 110 to the beamline assembly 114, wherein the source 120 comprises one or more extraction electrodes (not shown) to extract ions from the source chamber and thereby to direct the extracted ion beam 110 toward the beamline assembly 114.

The beamline assembly 114, for example, comprises a beamguide 130 having an entrance near the source 120 and an exit with a resolving aperture 134, as well as a mass analyzer 134 that receives the extracted ion beam 110 and creates a dipole magnetic field to pass only ions of appropriate energy-to-mass ratio or range thereof (e.g., a mass analyzed ion beam 110 having ions of a desired mass range) through the resolving aperture 132 to the substrate 105 on a workpiece scanning system 136 associated with the end station 116. Various beam forming and shaping structures (not shown) associated with the beamline assembly 114 may be further provided to maintain and bound the ion beam 110 when the ion beam is transported along a beam path to the substrate 105 supported on the workpiece scanning system 136.

The end station 116 illustrated in FIG. 1, for example, is a “serial” type end station that provides an evacuated process chamber in which the single substrate 105 (e.g., a semiconductor wafer, display panel, or other workpiece) is supported along the beam path for implantation with ions. It should be noted, however, that batch or other type end stations may alternatively be employed, and fall within the scope of the present invention. In an alternative aspect of the present invention, the system 100 comprises a beam scanning system (not shown) comprising a beam scanner that scans the ion beam in a substantially single beam scan plane with respect to the substrate 105 in order to provide a scanned ion beam to the substrate associated with the end station 116. Accordingly, all such scanned or non-scanned ion beams 110 are contemplated as falling within the scope of the present invention.

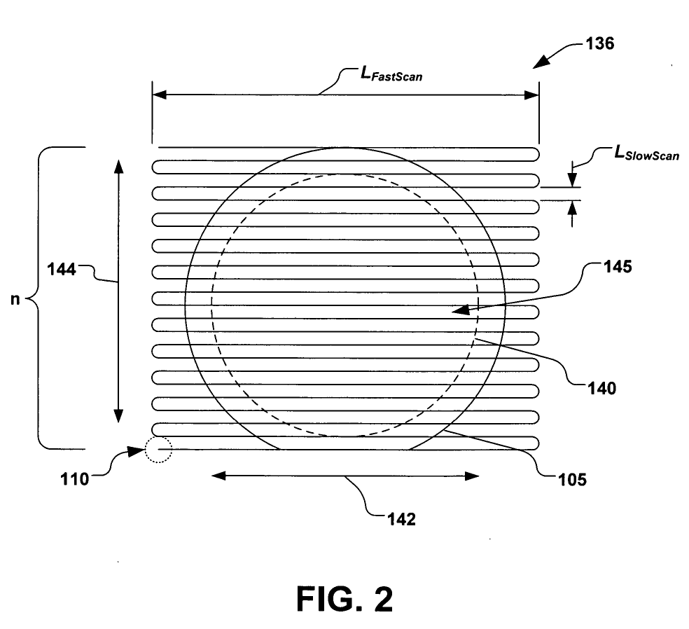

According to one exemplary aspect of the present invention, the single-substrate ion implantation system 100 provides a generally stationary ion beam 110 (e.g., also referred to as a “spot beam” or “pencil beam”), wherein the workpiece scanning system 136 generally translates the substrate 105 in two generally orthogonal axes with respect to the stationary ion beam. FIG. 2 illustrates a plan view of the exemplary workpiece scanning system 136 when viewed from the trajectory of the ion beam 110. The workpiece scanning system 136, for example, comprises a movable stage 140 whereon the substrate 105 resides, wherein the stage is operable to translate the substrate along a fast scan axis 142 and a generally orthogonal slow scan axis 144 with respect to the ion beam 110. A speed of the substrate 105 along the fast scan axis 142 (also referred to as the “fast scan direction”) is significantly faster than a speed of the substrate along the slow scan axis 144 (also referred to as the “slow scan direction”). For convenience, the speed of the substrate 105 along the fast scan axis 142 will be referred to as “fast scan speed”, and the speed of the substrate along the slow scan axis 144 will be referred to as “slow scan speed”.

In accordance with the present invention, in order to optimize the utilization of the ion beam 110, the fast scan speed and slow scan speed, for example, are variable, wherein one of a plurality of differing speeds in one or more of the fast scan direction 142 and slow scan direction 144 are selected, based on a set of performance criteria. The set of performance criteria, for example, comprises one or more of a desired maximum non-uniformity of the ion implantation across the substrate 105, a desired substrate throughput, a minimum ion beam current, and one or more desired substrate conditions, as will be discussed hereafter.

One important objective of the ion implantation system 100 of FIG. 1 is to provide both the correct number of ions in the substrate or wafer 105 from the ion beam 110 (e.g., a pencil or spot beam), referred to as a “dose”, as well as to provide a uniform distribution of the ions across a surface 145 of the wafer. Accordingly, the dose on the exemplary wafer 105 illustrated in FIG. 2, for example, can be calculated by:
Dose=U_{Beam}(I_{Beam}*t_{Implant}/e)/(A_{Wafer}) (1)
where U_{Beam} is a utilization of the ion beam 110, I_{Beam} is a current of the ion beam, t_{Implant} is a total implant time, e is the charge of an electron, and A_{Wafer} is the surface area 145 of the wafer 105. For a mechanical scan system, such as the system 100 of FIG. 1, the total implant time t_{Implant} generally allows for a predetermined number of mechanical scans across the surface 145 of the wafer 105, and wherein the wafer does not stop scanning with respect to the ion beam 110 while the ion beam is on the surface of the wafer. Therefore, an additional equation is:
t_{Implant}=n* L_{SlowScan}/V_{SlowScan} (2)
where L_{SlowScan} is the length of each slow scan pass, V_{SlowScan} is the speed of the substrate 105 along the slow-scan axis 144, and n is the number of scan passes in the slow-scan direction, as illustrated again in FIG. 2. It should be noted that the implant time t_{Implant} is largely determined by the ion beam current I_{Beam} and beam utilization U_{Beam}, thus placing and important constraint on the slow-scan scan speed V_{SlowScan}.

Another constraint on selecting scan speeds is given by the uniformity of the ion implantation across the wafer 105. Since the wafer 105 makes discrete passes through the ion beam 110 along the fast scan axis 142, the dose will have a ripple or “micro non-uniformity” effect along the slow scan axis 144 between each pass along the fast scan axis 142. For example, when viewed along a vertical line drawn through the center of the wafer 105 in the slow scan direction, ripple (not shown) can be seen between each fast scan pass. A period of the ripple, for example, is related to a distance advanced in the slow-scan direction with each sweep in the fast-scan direction. Accordingly:
T_{Ripple}=L_{FastScan}*(V_{SlowScan}/V_{FastScan}) (3)
where T_{Ripple} is the period of the ripple, and L_{FastScan} is the length of each fast scan pass, and V_{FastScan} is the speed of the substrate along the fast-scan axis 142.

It should be noted that the period T_{Ripple} is an approximation, and the actual ripple may be a multiple of T_{Ripple}, depending on fringing patterns between the scan frequencies. The amplitude of the ripple is generally difficult to calculate, and can vary significantly, depending on various factors, such as starting conditions of the system 100. Therefore, a general solution can be obtained wherein the dose at a particular point P is given by the summation of the dose accumulated during each fast-scan pass and slow-scan pass during the implant time. The dose for each fast-scan pass for each given point P can be calculated by integrating the beam profile at point P over the time it takes to make a single sweep. The total dose can therefore be calculated as the summation of each fast-scan pass or sweep over the number of slow-scan passes.

It should be noted that for multiple slow-scan passes, the location of a particular fast-scan pass may or may not correspond with the associated fast-scan pass from the previous slow-scan pass, depending on the synchronization of the two scan directions. However, for a given set of conditions, the ripple amplitude generally increases as the period increases. If, for example, the goal is to provide a highly uniform ion implant (e.g., a maximum non-uniformity having a standard deviation on the order of one percent across the substrate 105), it is useful to minimize the period by making the fast-scan speed much greater than the slow-scan speed. For example, in some ion implantation applications, the desired maximum non-uniformity of the ion implant has a desired standard deviation of approximately two percent across the substrate 105, while other applications have more stringent desired maximum non-uniformities, such as a uniformity having a standard deviation on the order of 0.5 percent or less across the substrate. The present invention, therefore, is operable to control one or more of the fast scan speed and slow scan speed, based, at least in part, on the desired maximum non-uniformity of the ion implantation across the substrate for varying implant applications.

While the above constraints are generally related to the implant time, another term in equation (1) is the beam utilization U_{Beam}. For any given two-dimensional scanning system, a time required to stop and reverse direction with each scan is significant to productivity, therein making the utilization further dependent on the fast-scan speed and slow-scan speed. To maintain uniformity, the wafer 105 is overscanned, as illustrated again in FIG. 2, wherein the wafer is scanned beyond the edge 150 thereof by a distance D approximately equal to a diameter of the ion beam 110 (e.g., a diameter of a circular cross-section spot beam). Assuming constant acceleration and deceleration, the time t_{scan} required for each fast-scan pass is:
t_{scan}=((D_{Wafer}+D_{Beam})/V_{FastScan})+2*V_{FastScan}/a (4)
where a is a value of the acceleration and deceleration of the substrate 105. To calculate utilization, it is convenient to express the time t_{scan} in terms of an equivalent scan length, which is defined as the distance traveled during time t_{scan}, assuming a constant speed and zero acceleration and deceleration time. By converting to a length, the calculation of ion beam utilization is simplified in comparing to the wafer area. Therefore, the equivalent length can be calculated as:
L_{FastScan}=V_{FastScan}*t_{scan} (5)
thus:
L_{FastScan}=D_{Wafer}+D_{Beam}+2*V_{FastScan}²/a (6).
Similarly for the slow-scan axis:
L_{SlowScan}=D_{Wafer}+D_{Beam}+2*V_{SlowScan}²/a (7).

Beam utilization can be consequently computed directly from the ratio of the wafer area A_{Wafer} to the scan area:
U_{Beam}=A_{Wafer}/(L_{FastScan}*L_{SlowScan}) (8).
Therefore, for a given set of conditions, ion beam utilization decreases as the scan speeds increase. Accordingly, in order to increase ion beam utilization, it is useful to set the scan speeds as slow as possible, while setting the accelerations as high as possible. Since the fast-scan speed is generally much larger than the slow-scan speed (e.g., wherein the frequency of oscillation in the fast-scan direction 142 ranges between approximately 1 Hz and approximately 5 Hz for single-wafer scanning and between approximately 10 Hz and approximately 15 Hz in multi-wafer scanning, and wherein the frequency of oscillation in the slow-scan direction 144 ranges between approximately 0.05 Hz and approximately 0.2 Hz), the utilization is dominated by mechanics in the fast-scan direction.

Therefore, in order to optimize the ion beam 110, a selection of one of a plurality of scan speeds in the fast scan direction 142 and one of a plurality of scan speeds in the slow scan direction 144 for the exemplary two-dimensional scan system 100 is dependent on multiple variables. Accordingly, as will be appreciated from the above discussion, increasing the slow-scan speed will generally decrease the minimum implant time. Furthermore, increasing the ratio of the fast-scan speed to the slow-scan speed will generally Improve uniformity. Still further, decreasing the fast-scan speed and increasing acceleration in the fast-scan direction will generally improve the ion beam utilization.

According to another exemplary aspect of the invention, one solution for optimizing the ion beam utilization efficiency is to design the ion implantation system 100 for a set of conditions associated with the system and/or substrate 105, wherein the system is configured to be less efficient at other conditions. Accordingly, the ion implantation system 100 of the present invention and method of optimization thereof provides for a range of variable fast-scan speeds and slow-scan speeds wherein the fast-scan speeds and slow-scan speeds can be optimized for each implant condition. For example, the optimization is based, at least in part, on a size of the ion beam 110 and an ion distribution that is measured during a setup of the ion implantation system 100, therein providing a high level of optimization via empirical data. An alternative example comprises utilizing ion beam parameters, such as energy, species, dosage, and ion beam current to predict the beam size, and then optimizing the system 100 based on a predicted beam size, wherein the prediction is based on the ion beam parameters. As will be appreciated, such a predictive approach advantageously provides a fast setup for the ion implantation system.

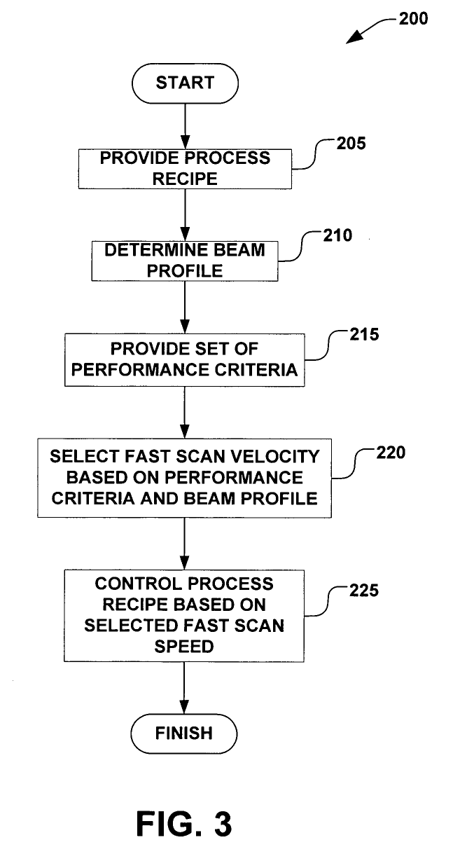

According to still another exemplary aspect of the present invention, FIG. 3 is a schematic block diagram of an exemplary method 200 illustrating an exemplary optimization of an ion implantation system, such as the exemplary ion implantation system 100 of FIG. 1. While exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

As illustrated in FIG. 3, the method 200 begins with act 205, wherein a process recipe for the ion implantation is provided. The process recipe, for example, comprises one or more of a desired ion beam current, a size of the ion beam, a number of passes made by the substrate through the ion beam in the slow scan direction, a desired dosage of ions implanted into the substrate, and a speed of the substrate in the slow scan direction. From the process recipe, a profile of the ion beam is determined in act 210. The ion beam profile, for example, is determined from empirical data, or alternatively, is predicted, based on the process recipe.

In act 215, a set of performance criteria is provided, wherein the performance criteria comprises one or more of a desired maximum non-uniformity of the ion implantation across the substrate, a desired substrate throughput, a minimum ion beam current, and one or more desired substrate conditions. The maximum desired non-uniformity, for example, is determined based on an amount of ripple deemed to yield acceptable results in future processing of the substrate. The one or more desired substrate conditions, for example, comprise one or more of a maximum substrate temperature (e.g., a desired maximum temperature of the substrate caused by heating from the ion beam), substrate charging, susceptibility of the substrate to beam current changes and dropouts, as well as a maximum momentum of the substrate, wherein, for example, a limit in the range of fast-scan speeds can be further introduced. The maximum momentum of the substrate, for example, is based on a grip of the movable stage 140 of FIG. 1 to the substrate 105, or alternatively, on a power requirement for moving the stage.

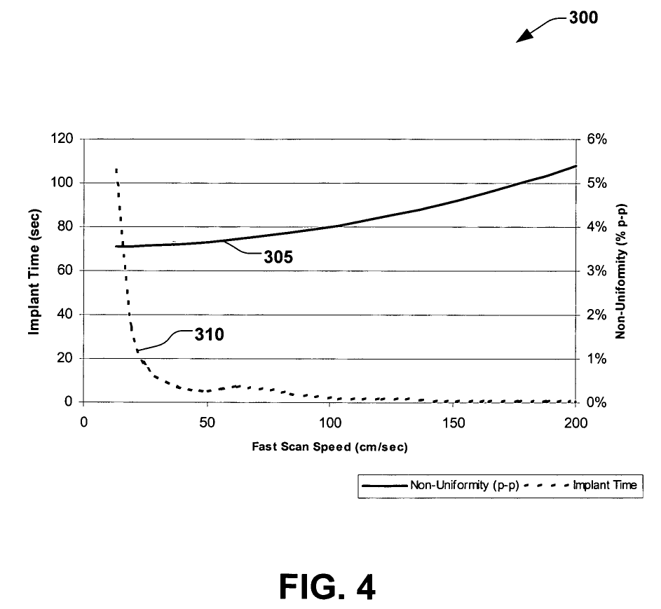

In act 220 of FIG. 3, one of a plurality of differing speeds of the substrate in the fast scan direction is selected, wherein the selection is based, at least in part, on the determined ion beam profile and the set of performance criteria. For example, FIG. 4 is a graph 300 illustrating a simulation of the trade-off between ion implant non-uniformity 305 and implant time 310 (e.g., a total time to complete an ion implantation on a wafer). The graph 300 is illustrates exemplary non-uniformities and implant times for an ion implantation having an exemplary dose of 5×10¹⁴ cm² (i.e. ions per square centimeter), an ion beam current of 2 mA, a single slow-scan pass of a 300 mm diameter wafer, and using an 8 cm parabolically-distributed ion beam. The implant time 310, for example, is varied by varying the fast-scan speed, and non-uniformity 305 is defined by peak-to-peak variation in dose. For example, assuming a desired non-uniformity of less than 0.5% peak-to-peak, a fast-scan speed would be approximately 30 cm/sec, leading to an implant time of approximately 71 seconds. In comparison, if the system were designed to provide a fast-scan speed operate of 200 cm/sec, the implant time would be approximately 107 seconds. In such a case, the productivity of the ion implant would be improved by approximately 33% by optimizing the fast-scan speed from 30 cm/sec to 200 cm/sec.

Now, referring again to the method 200 of FIG. 3, act 225 illustrates a control of the process recipe, wherein the control is based, at least in part, on the selected fast scan speed. Such a control, for example, comprises controlling or adjusting one or more of the process recipe parameters, again comprising the desired ion beam current, size of the ion beam, number of passes through the ion beam in the slow scan direction, desired dosage of ions implanted into the substrate, and speed of the substrate in the slow scan direction, wherein the control is based on the previously-selected fast scan speed.

In accordance with another exemplary aspect of the invention, another one of the plurality of differing speeds in the fast direction is selected after controlling the process recipe in act 225, wherein the selection is based, at least in part, on another ion implantation on another substrate associated with the controlled process recipe and the performance criteria. Accordingly, the optimization method 200 can be performed iteratively, wherein changing one or a plurality of variables associated one or more of the process recipe, performance criteria, fast scan speed, and slow scan speed will have an impact the other variables. For example, changing the fast-scan speed may change the utilization of the ion beam, and therefore, will change the slow scan speed required to achieve the desired dose.

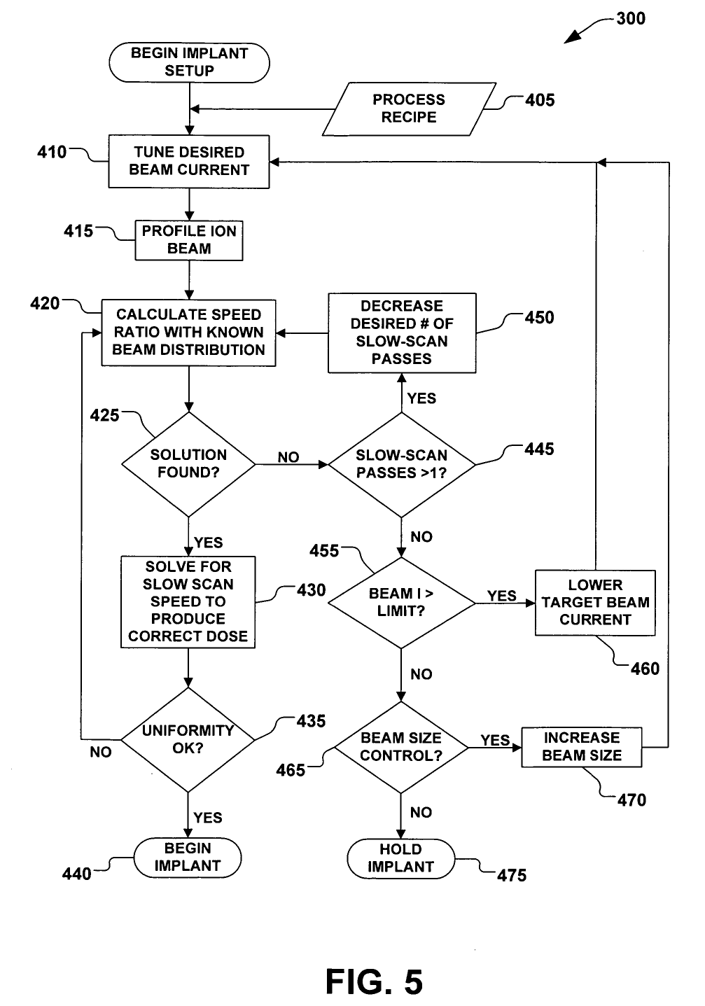

Referring now to FIG. 5, another exemplary method 400 for optimizing an ion implantation system is illustrated. The method 400 begins with providing a process recipe 405 for the ion implantation system, wherein the process recipe comprises parameters such as a desired current of the ion beam, a number of passes through the ion beam in the slow scan direction, a maximum non-uniformity of the ion implantation across the substrate, and a dosage of ions to be implanted into the substrate. In act 410, the ion implantation system is tuned, based on the process recipe, wherein, for example, the ion beam current is controlled to match the desired ion beam current. The ion beam is then profiled in act 415, wherein a size of the ion beam is generally determined. In act 420, a speed ratio between the fast-scan speed and slow-scan speed is determined, wherein the determined speed ratio is determined based, at least in part, on the maximum non-uniformity of the ion implantation and an ion beam distribution based on the process recipe.

In act 425, a determination is made as to whether an acceptable speed ratio solution is found, based on the desired parameters from the process recipe. If a solution is found in act 425, one of a plurality of slow-scan speeds is determined in act 430, wherein the determination is based, at least in part, on the desired dosage of the ion implantation. For example, the determination in act 430 comprises calculating the slow-scan speed based on the fast-scan speed and the process recipe. In act 435, another determination is made as to whether the uniformity of the ion implantation is acceptable, based on the desired maximum non-uniformity. If the uniformity is acceptable, then the ion implantation can begin on a substrate in act 440. If, however, the determination in act 435 is such that the uniformity is greater than the desired maximum non-uniformity, another speed ratio is again calculated in act 420, and the process is repeated.

If the determination in act 425 is such that no speed ratio solution is found, a determination is made in act 445 as to whether the number of slow-scan passes is greater than a single pass. If the answer to the determination of act 445 is positive, then the desired number of slow-scan passes is decreased in act 450, and another speed ratio is again calculated in act 420. If, however, only a single slow scan pass is determined in act 445, a determination is made in act 455 as to whether the ion beam current is greater than a desired minimum ion beam current. If the ion beam current is greater than the desired minimum ion beam current, then the beam current is lowered to a lower ion beam current in act 460, and the ion implantation system is again tuned in act 410, based on the lower ion beam current. If, however, the determination in act 455 is made such that the beam current is less than or equal to the desired minimum beam current, then a determination is made in act 465 as to whether a size of the ion beam can be increased. If the size of the ion beam can be increased, in accordance with limitations associated with the ion implantation system, then the ion beam size is increased appropriately in act 470, and the ion implantation system is again tuned, based on the increased ion beam size. If, however, the size of the ion beam cannot be increased, for example, due to limitations in the ion implantation system or other limitations, then the ion implantation system is determined to be unacceptable for producing an acceptable ion implantation according to the desired process parameters, and the ion implantation is put on hold in act 475.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application.

1. A method for optimizing a utilization of an ion beam during an ion implantation into a substrate, wherein the substrate passes through the ion beam in a fast scan direction and a generally orthogonal slow scan direction, the method comprising:
providing a process recipe for the ion implantation;
predicting a profile of the ion beam, wherein the prediction is based on the process recipe;
providing a set of performance criteria comprising one or more of a desired maximum non-uniformity of the ion implantation across the substrate, a desired substrate throughput, a minimum ion beam current, and one or more desired substrate conditions;
selecting one of a plurality of differing speeds of the substrate in the fast scan direction, based on the predicted ion beam profile and the set of performance criteria; and
controlling the process recipe, based on the selected fast scan speed.

2. The method of claim 1, wherein the process recipe comprises one or more of a desired ion beam current, a size of the ion beam, a number of passes through the ion beam in the slow scan direction, a desired dosage of ions implanted into the substrate, and a speed of the substrate in the slow scan direction.

3. The method of claim 2, further comprising selecting another one of the plurality of differing speeds in the fast direction after controlling the process recipe, based, at least in part, on an ion implantation associated with the controlled process recipe and the performance criteria.

4. The method of claim 1, wherein the one or more desired substrate conditions comprise one or more of a maximum substrate temperature and a maximum momentum of the substrate.

5. (canceled)

6. The method of claim 1, wherein the desired maximum non-uniformity has a standard deviation on the order of one percent across the substrate.

7. The method of claim 1, wherein the substrate oscillates in the fast scan direction between approximately 1 Hz and approximately 15 Hz, and wherein the substrate oscillates in the slow scan direction between approximately 0.05 Hz and approximately 0.2 Hz.

8. The method of claim 1, further comprising controlling the fast scan speed based on the controlled process recipe, predicted ion beam profile, and set of performance criteria.

9. A method for optimizing a utilization of an ion beam during an ion implantation into a substrate, wherein the substrate passes through the ion beam in a fast scan direction and a generally orthogonal slow scan direction, the method comprising:
providing a process recipe for the ion implantation, the process recipe comprising one or more of a current of the ion beam, a dosage of ions, and a number of passes of the substrate through the ion beam in the slow scan direction;
profiling the ion beam based on the process recipe, wherein a size of the ion beam is determined;
selecting one of a plurality of differing speeds of the substrate in the fast scan direction, based, at least in part, on a desired maximum non-uniformity of the ion implantation and the process recipe;
controlling the process recipe, based on one or more of the desired maximum non-uniformity, a throughput time for the substrate, a desired minimum ion beam current, and one or more substrate conditions; and
selecting one of a plurality of speeds in the slow scan direction, based on the dosage of the ion implantation.

10. The method of claim 9, further comprising selecting another one of the plurality of speeds in the fast scan direction after controlling the process recipe, based on a uniformity of an ion implantation associated with the controlled process recipe.

11. The method of claim 9, wherein selecting the one of the plurality of speeds in the fast scan direction is further based on one or more desired substrate conditions.

12. The method of claim 11, wherein the one or more substrate conditions comprise one or more of a maximum substrate temperature and a maximum momentum of the substrate.

13. The method of claim 9, wherein the ion beam profile is determined based on one or more of empirical data and a prediction of the beam profile based on the process recipe.

14. The method of claim 9, wherein the desired maximum non-uniformity has a standard deviation on the order of one percent across the substrate.

15. The method of claim 9, wherein the substrate oscillates in the fast scan direction between approximately 1 Hz and approximately 15 Hz, and wherein the substrate oscillates in the slow scan direction between approximately 0.05 Hz and approximately 0.2 Hz.
